(19) United States
(12) Patent Application Publication
(10) Pub. No.: US 2004/0018735 A1
(43) Pub. Date: Jan. 29, 2004

(54) Method of depositing an oxide film by chemical vapor deposition

(76) Inventors: Seung G. Park, Scotts Valley, CA (US); Lawrence D. Bartholomew, Felton, CA (US); Soon K. Yuh, Scotts Valley, CA (US)

Correspondence Address: DORSEY & WHITNEY LLP, INTELLECTUAL PROPERTY DEPARTMENT, 4 EMBARCADERO CENTER, SUITE 3400, SAN FRANCISCO, CA, 94111, US

(21) Appl. No.: 10/442,423

(22) Filed: May 20, 2003

Related U.S. Application Data
(60) Provisional application No. 60/382,780, filed on May 21, 2002.

(51) Int. Cl. H01L 21/311

(52) U.S. Cl. 438/700

(57) ABSTRACT

A method of depositing a silicon dioxide film on the surface of a semiconductor substrate or wafer is particularly useful for improved film integrity on difficult topologies such as sub-0.1 micron topologies, high aspect ratio trenches in sub-micron topologies, sidewalls having slight overhangs at layer interfaces, and sidewalls having slightly reentrant areas. In one embodiment, the method involves the deposition of successive thin layers with a silicon-containing source and an oxygen-containing source, each layer deposition being preceded by a pre-treatment of the prior layer involving exposure of the surface to an oxygen-containing source without a silicon-containing source. The deposition of multiple thin silicon dioxide layers continues until a film of desired thickness is formed. For structures containing trenches to be filled, each thin layer is less than half the width of the smallest trench so that preferably multiple layers are used to fill the trenches.

### CROSS-REFERENCE TO RELATED APPLICATION

This application claims priority to and the benefit of U.S. Provisional Application Serial No. 60/382,780, filed May 21, 2002, which hereby is incorporated herein in its entirety by reference thereto.

### BACKGROUND OF THE INVENTION

1. Field of the Invention

The present invention relates generally to the field of semiconductor processing. More particularly, the present invention relates to a method of depositing doped and undoped oxide films to provide improved film integrity, uniformity of composition, and gap fill.

2. Description of Related Art

Deposition of dielectric and other films or layers are widely employed in the processing of semiconductors. Chemical vapor deposition (CVD), both at atmospheric and sub-atmospheric pressures, as well as plasma enhanced CVD methods, are widely used in the semiconductor industry to deposit films such as doped and undoped silicon oxides and nitrides on the surface of the semiconductor substrates or wafers. Providing the capability for void free gap fill of good integrity films has been of extreme interest in the semiconductor industry since the introduction of CVD techniques. As semiconductor device densities continue to increase and the device structures become smaller with greater aspect ratios, the gap fill requirements of such films becomes even more rigorous.

While many deposition processes are available, the prior state of the art methods, particularly for the deposition of silicon dioxide (SiO₂) and doped oxides such as boron-phospho-silicate glass (BPSG) and the like, have deficiencies. For example, while as-deposited undoped SiO₂ oxide film step coverage from a CVD process using TEOS & O₃ may appear to be adequate to yield gap-fill of sub-0.1 μm structures when viewed by cleaving and taking SEM photographs without any etch decoration, as-deposited doped BPSG, boron silicate glass (BSG), and phospho silicate glass (PSG) oxide films do not exhibit adequate gap-fill step coverage for sub-0.1 μm structures when viewed by cleaving and taking SEM photographs without any etch decoration. Significant voids are present in as-deposited doped films due to poor conformality of only about 95% (rather than 100%) when dopant source chemicals such as TEB, TEPo, TMB, or TMPi are added.

When undoped SiO₂ films deposited from TEOS & O₃ in a prior art CVD process are viewed in SEM photographs of the cleaved structures with etch decoration, weak seams are observed. Thus the integrity and composition of the deposited film is different where the surfaces grow together as the sub-0.1 μm gap is filled.

Even subsequent annealing does not necessarily result in satisfactory gap fill or seam strength upon wet etch decoration. While undoped SiO₂ films annealed at a high temperature, such as about 1000° C., show full gap-fill as-annealed when cleaved, weak seams are apparent after etch decoration. Even where annealing could be helpful, the thermal budget of the device may not allow sufficient annealing. Consider, for example, the annealing of doped BPSG films. Typically such annealing is done over 700° C. to cause plastic deformation and flow (due to the lower melting point of the glass) in order to fill any as-deposited voids that are present. However, where lower thermal budgets are required, annealing may not yield complete gap-fill when lower temperatures and times are utilized. While the occurrence of weak seams or voids upon etch decoration may also be reduced by changing the ambient gas during an anneal process from N₂ to O₂ to H₂O (steam), the accelerated thermal oxidation in the presence of steam may not be tolerated by the device geometry requirements.

Accordingly, many deficiencies are present in the prior art, and an improved method for deposition of oxide films is needed.

### BRIEF SUMMARY OF THE INVENTION

One embodiment of the invention is a method of forming a doped or undoped silicon-containing film upon a substrate having trenches therein, comprising pre-treating the substrate by chemical exposure in the absence of a silicon-containing source to improve uniformity within the trenches of a surface concentration of sites that are receptive to gas phase silicon-containing intermediates; forming a layer of silicon-containing material upon the substrate by exposure of the substrate to a chemical vapor deposition gas source combination comprising an oxygen-containing source and a silicon-containing source; and repeating the pre-treating step and the forming step to form a uniform film within the trenches.

Another embodiment of the invention is a method of forming a doped or undoped silicon dioxide film comprising successively depositing thin layers of doped or undoped silicon dioxide with chemical vapor deposition using an oxygen-containing source and a silicon-containing source to obtain a film of a desired thickness; and between each of the successive thin layer depositions, decomposing the oxygen-containing source in the absence of the silicon-containing source.

A further embodiment of the invention is a method of forming a doped or undoped silicon dioxide film upon a substrate, comprising forming a first layer of doped or undoped silicon dioxide with chemical vapor deposition; oxidizing the first layer; and forming a second layer of doped or undoped silicon dioxide contiguous with the first layer with chemical vapor deposition.

### BRIEF DESCRIPTION OF THE SEVERAL VIEWS OF THE DRAWINGS

FIG. 1 is a cross-section drawing of illustrative trenches prior to undoped or doped SiO₂ deposition, the trenches having overhang in their sidewalls.

FIG. 2 is a cross-section drawing of illustrative trenches prior to undoped or doped SiO₂ deposition, the trenches being reentrant.

FIG. 3 is a cross-section drawing of illustrative trenches prior to undoped or doped SiO₂ deposition, the trenches having high aspect ratios.

FIG. 4 is a flowchart showing an illustrative embodiment of an improved method of depositing an undoped or doped silicon dioxide film on the surface of a semiconductor substrate or wafer.

FIG. 5 is a graphical representation of an SEM photograph of an etch decorated series of trenches in an STI topology which were filled with undoped SiO₂ by a process in accordance with the present invention.

FIG. 6 is a graphical representation of an SEM photograph of an etch decorated series of trenches that is identical to that of FIG. 5, but which were annealed after filling with undoped SiO₂.

FIG. 7 is a graphical representation of an SEM photograph of an etch decorated open trench and step which were conformally coated with undoped SiO₂ by a process in accordance with the present invention.

FIG. 8 is a graphical representation of an SEM photograph of an etch decorated series of trenches that is identical to that of FIG. 5, but which were incompletely filled with undoped SiO₂ deposited by TEOS and O₃ without pretreatment.

FIG. 9 is a graphical representation of an SEM photograph of an etch decorated series of trenches that is identical to that of FIG. 8 filled with the same prior art process, except that the wafer was subsequently annealed.

### DETAILED DESCRIPTION OF THE INVENTION

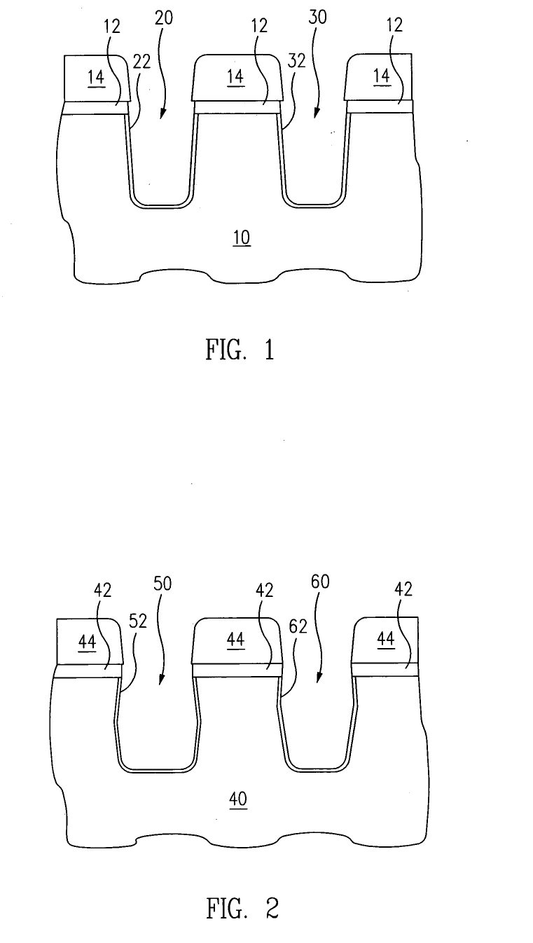

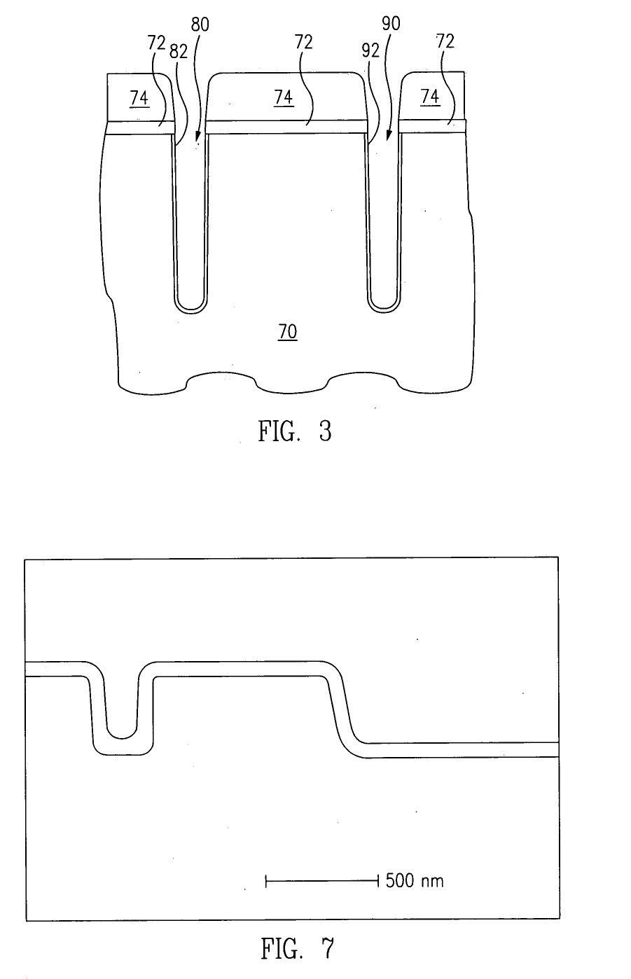

An improved method of depositing a silicon dioxide film on the surface of a semiconductor substrate or wafer is particularly useful for improved film integrity on difficult topologies, including but not limited to sub-0.1 micron topologies, high aspect ratio trenches in sub-micron topologies, sidewalls having slight overhangs at layer interfaces, and sidewalls having slightly reentrant areas. As used herein, the term “trench” includes both line trenches, circular vias, and other such topology features. These problems are illustrated in FIG. 1, FIG. 2 and FIG. 3.

FIG. 1 is a cross-section drawing of illustrative trenches 20 and 30 prior to SiO₂ deposition. The trenches 20 and 30 are formed in a silicon substrate 10 using a silicon nitride etch mask 14, illustratively about 1000 Å to 2000 Å thick, deposited over a thermal oxide layer 12, illustratively about 30 Å to 100 Å thick. The trenches 20 and 30 are etched using any suitable etch technique, and typically have a thin thermal oxide layer 22 and 32 which illustratively are about 10 Å to 50 Å thick on their sidewalls and bottoms. The silicon nitride etch mask 14 illustratively overhangs the trenches 20 and 30.

FIG. 2 is a cross-section drawing of illustrative trenches 50 and 60 prior to SiO₂ deposition. The trenches 50 and 60 are formed in a silicon substrate 40 using a silicon nitride etch mask 44, illustratively about 1000 Å to 2000 Å thick, deposited over a thermal oxide layer 42, illustratively about 30 Å to 100 Å thick. The trenches 50 and 60 are etched using any suitable etch technique, and typically have a thin thermal oxide layer 52 and 62 which illustratively are about 10 Å to 50 Å thick on their sidewalls and bottoms. The trenches 20 and 30 illustratively have reentrant sidewalls.

FIG. 3 is a cross-section drawing of illustrative trenches 80 and 90 prior to SiO₂ deposition. The trenches 80 and 90 are formed in a silicon substrate 70 using a silicon nitride etch mask 74, illustratively about 1000 Å to 2000 Å thick, deposited over a thermal oxide layer 72, illustratively about 30 Å to 100 Å thick. The trenches 80 and 90 are etched using any suitable etch technique, and typically have a thin thermal oxide layer 82 and 92 which illustratively are about 10 Å to 50 Å thick on their sidewalls and bottoms. The trenches 20 and 30 illustratively are high aspect ratio trenches.

In one embodiment, the method involves the deposition of successive thin layers with a silicon-containing source and an oxygen-containing source, each layer deposition being preceded by a pre-treatment of the prior layer involving exposure of the surface to an oxygen-containing source without a silicon-containing source. The deposition of multiple thin silicon dioxide layers continues until a film of desired thickness is formed. Any suitable semiconductor processing equipment may be used for alternating between pre-treatment and deposition, including equipment with multiple chambers or with multiple injectors in one chamber, as well as equipment capable of selectively applying the various sources for sustained periods of time through a single injector or selectively pulsing the various sources through a single injector. For structures containing trenches to be filled, each thin layer is less than half the width of the smallest trench to be filled so that preferably multiple layers are used to fill all trenches to be filled.

Suitable silicon-containing sources include but are not limited to tetraethylorthosilicate (TEOS), silane, TMCTS, OMCTS, HMDSO, TMDSO, and the like. Suitable oxygen-containing sources useful for the deposition including but are not limited to ozone, ozone mixed with oxygen and nitrogen, N₂O, oxygen, water, and the like. Where oxygen without ozone is used, atomic oxygen for oxidization may be obtained by plasma or otherwise energizing the oxygen, as is well known in the art. When TEOS is used as the silicon source, for example, the oxygen-containing source preferred during deposition is ozone delivered with oxygen and a little nitrogen for stabilization. Suitable pre-treatment sources depend on the specific material of the layer being pre-treated, and include but are not limited to ozone, ozone mixed with oxygen and nitrogen, oxygen, isopropyl alcohol, ethanol alcohol, water, hydrogen, and NF₃. When the material being pretreated is undoped silicon dioxide, for example, the pretreatment source preferred is ozone delivered with oxygen and a little nitrogen for stabilization. The source used in pre-treatment and the oxidizer source used in deposition need not necessarily be the same substance.

Of particular advantage, the method of film deposition described herein achieves good film integrity and gap fill of sub-micron trenches, whether using doped or undoped silicon dioxide. Any suitable dopant may be employed. When a doped film is deposited, the dopant precursor is conveyed during deposition along with the silicon-containing and oxygen-containing sources.

The pretreatment surface reaction yielding the improvement in oxide (such as SiO₂) integrity and gap fill capability may be due to different phenomena. While not intending to be bound by any one particular theory, one possibility is that where an oxidizer is used for the pretreatment, the active atomic oxygen generated from the decomposition of the oxygen-containing source in the absence of the silicon-containing source accomplishes a more thorough conversion of the singly bound surface Si(g1)-(C₂H₄OH)₃ to triply bound Si(g3)-OH via emission of ethylene and ethanol. This may make the surface concentration of triply bound Si(g3)-OH sites that are receptive to the gas phase silicon-containing intermediates for subsequent SiO₂ deposition more uniform throughout the trench. Processes that do not provide the extra time for surface reaction during injection of the oxidizer (such as O₃) in the absence of the silicon-containing source (such as TEOS) may allow the concentration of triply bound Si(g3)-OH sites to be much greater on the exposed upper trench corners where the incident flux of radicals is greater, relative to the concentration of triply bound Si(g3)-OH sites down inside the small gaps near the bottom of the trenches. As the TEOS is injected along with the O₃ under these circumstances, the growth rate of SiO₂ may be enhanced at the upper trench corners, compared to the growth rate in the bottom of the trenches. However, by interrupting the deposition periodically to provide extra time for surface reaction during injection of the oxidizer in the absence of the silicon-containing source, the surface distribution of species that yield film growth may become uniform both inside the trenches as well as outside the gaps requiring filling, thereby promoting improvement in step coverage, gap-fill capability, and film integrity.

In addition, the conversion of the singly bound surface Si(g1)-(C₂H₄OH)₃ to triply bound Si(g3)-OH may also reduce the sticking coefficient of gas phase intermediates that contribute to film growth, such as, for example, Si(OC₂H₅)₃—OH, thus improving step coverage inside the trenches.

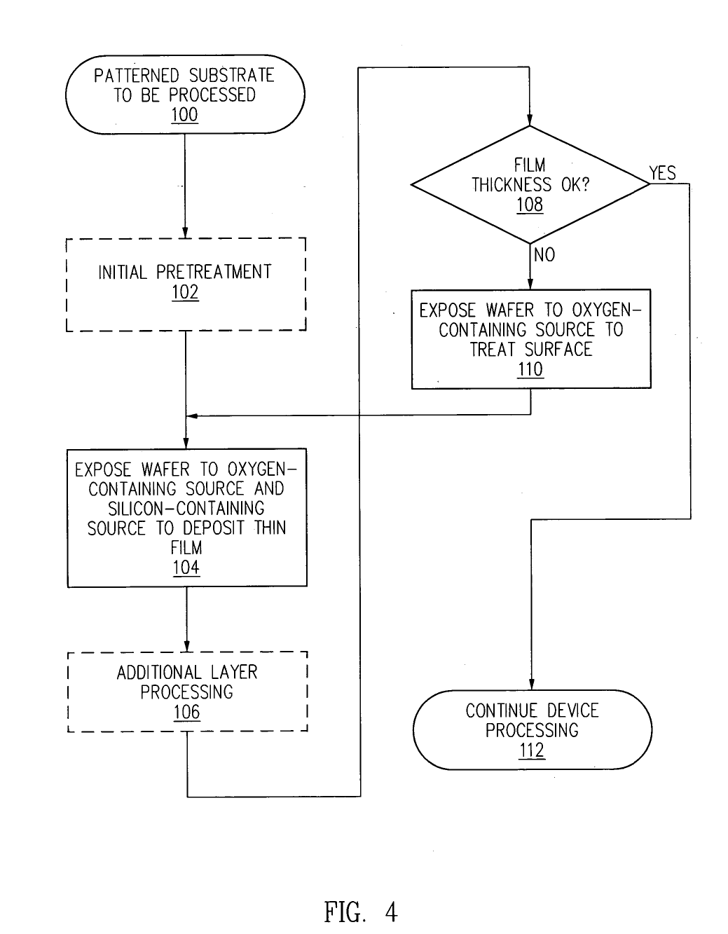

FIG. 4 is a flowchart showing an illustrative embodiment of an improved method of depositing a silicon dioxide film on the surface of a semiconductor substrate or wafer that yields improved film integrity and gap-fill in difficult topologies. Filling trenches with high integrity silicon oxide can be difficult, since trenches typically are formed between stacked structures so that the trench sidewalls have various discontinuities such as slight overhangs (see FIG. 1) or slight ledges at layer interfaces, and reentrant angles (see FIG. 2). The silicon dioxide is required to completely fill the trenches without gaps and with no significant seam weakness, i.e., the integrity of the film should be sufficient to withstand wet etch solutions without excessive non-isotropic behavior. The process of FIG. 4 is described with reference to TEOS as the silicon-containing source and ozone as the oxygen-containing source, which are employed to deposit an undoped silicon dioxide film in trenches.

The method of FIG. 4 is suitable for depositing SiO₂ film on any semiconductor substrate surface, but is particularly advantageous for use on difficult topologies. Where trenches and steps are present, their sidewalls may present a variety of different materials, including but not limited to bare silicon, thin thermal oxide, silicon nitride, silicon oxynitride, and so forth. The semiconductor substrate optionally is initially treated or exposed to a pretreatment that is appropriate for the material on the sidewalls (block 102). Where the sidewalls are coated with thin thermal oxide, for example, the initial exposure of the surface illustratively is to an O₃, O₂ and N₂ ambient without any silicon-containing source precursor to avoid oxide deposition at first. The substrate is kept at a normal deposition temperature of about 530° C., although other temperatures may be used if desired. The time of this initial exposure may also vary, although in this example the surface is exposed for a time of about 30 seconds.

TEOS or some other silicon-containing precursor is then introduced along with the O₃, O₂ and N₂ to initiate CVD deposition (block 104). Preferably, only a thin layer of SiO₂ is deposited, the layer being a fraction of that required to close the smallest trench. As an example, where the smallest gap is on the order of 0.135 microns, a suitable layer thickness is about 200 Å. Roughly speaking, the layer thickness may be on the order of one-seventh to one-tenth of that required to close the gap, although the layer thickness may be smaller or larger. Moreover, each layer need not be the same thickness.

Although in this example the same oxygen-containing source is used for the initial pretreatment and the deposition, a different pretreatment source may be used than the oxygen-containing source used for the deposition.

Optionally, additional layer processing 106 may be performed at this time. An example of one type of additional layer processing is to raise the wafer temperature to achieve a degree of annealing or densification of the just-deposited layer, followed by a lowering of the wafer temperature to the normal deposition temperature.

If the film thickness is not sufficient after layer deposition (block 108—no), the most recently deposited SiO₂ layer on the surface is pre-treated with O₃, O₂ and N₂ for a sufficient time, in this case about 30 seconds (block 110). No silicon-containing source precursor is used, so no oxide deposition occurs. Although in this example the oxygen-containing source used for pretreatment is the same as that used in deposition, a different oxygen-containing source may be used, if desired.

The TEOS or other silicon precursor is then introduced again along with the O₃, O₂ and N₂ to resume CVD deposition (block 104). Again only a thin layer of SiO₂ is deposited, which in this example is about 200 Å. Optionally, additional layer processing 106 may be performed if desired.

This process (block 108—no, block 110, block 104, and optionally block 106) is repeated at least until a sufficient number of layers have been deposited to fill the trenches that are required to be filled (block 108—yes). The total film thickness required to fill all the different structure gaps is thus deposited by alternating surface pretreatment with an oxygen-containing source with thin layer deposition of SiO₂.

Although in this example the same silicon-containing source and the same oxygen-containing source are used for each deposition, a different silicon-containing source and/or a different oxygen-containing source may be used for different depositions, if desired.

The method of the present invention may be carried out in any type of CVD reactor having the capability of exposing a silicon wafer alternately between an oxygen-containing source and the combination of an oxygen-containing source with a silicon-containing source. In one example of a suitable CVD reactor, the precursors are delivered by a linear gas injector such as the system described in U.S. Pat. No. 5,683,516 issued Nov. 4, 1997 to DeDontney et al., and U.S. Pat. No. 6,022,414 issued Feb. 8, 2000 to Miller et al., which are hereby incorporated herein in their entirety by reference thereto. In another example of a suitable CVD reactor, the precursors are delivered as described in U.S. patent application Ser. No. 09/483,945, filed Jan. 13, 2000 in the name of Savage et al. and entitled “Semiconductor wafer processing system with vertically-stacked process chambers and single-axis dual-wafer transfer system,” which is hereby incorporated herein in its entirety by reference thereto. Other types of CVD systems such as showerhead injector systems and the like, may also be used.

The method of FIG. 4 may alternatively be practiced using a rapid pulsing technique that deposits a thin layer on the order of only about 10 Å-20 Å during each deposition. In this embodiment, the oxygen-containing source and the combined silicon-containing source and oxygen-containing source are alternated every few seconds. Reactors used for atomic layer deposition are generally capable of rapidly pulsing single precursors, and may be modified to rapidly pulse between the single oxygen-containing source and the dual silicon-containing source and oxygen-containing source.

The following experimental examples are presented to describe how seam weakness inside of narrow trenches inherent in some prior art processes may be observed, and to describe specific embodiments of the FIG. 4 method in which an as-deposited undoped silicon dioxide film does not exhibit such seam weakness problems upon etch decoration. The method of FIG. 4 generally extends the smallest gap dimension and the highest aspect ratio of the trenches filled with undoped as-deposited silicon dioxide, without encountering significant seam weakness as observed upon etch decoration. However, the method of FIG. 4 may also be used to deposit doped silicon dioxide, if desired. The following experiments are provided for illustration purposes only, and are in no way intended to limit the present invention as set forth in the claims below.

Semiconductor wafers were processed according to one embodiment of the method of the present invention in a chemical vapor deposition system of the type described in the aforementioned U.S. patent application Ser. No. 09/483,945. A SiO₂ film was formed by a sequence alternating between a 30 second duration pre-treatment pass under a 300 mm 4X MultiBlok® injector with only O₃ on, and a 40 second duration SiO₂ deposition pass under the 300 mm 4X MultiBlok® injector with both O₃ and TEOS on. Each of the multiple thin ˜200 Å layers of SiO₂ were deposited using 70 sccm of TEOS injected from each of the two bubblers (A & B) for a total of 140 sccm TEOS in one chamber. The O₂ flow through the O₃ generator was 45 slm with an O₃ concentration of 130 g/m³, yielding 2.73 slm of pure O₃. So the O₃:R ratio used in this 8-cycle test at a deposition temperature of 530° C. was 19.5:1.

FIG. 5 is a graphical representation of an SEM photograph of a series of trenches in a shallow trench isolation (STI) topology which were filled with undoped SiO₂ in accordance with the foregoing process. Each of the trenches has a width of about 0.135 microns and a depth of about 0.38 micron, yielding an aspect ratio of 2.8:1. The as-deposited SiO₂ film shows complete gap fill after etch decoration in 20:1 buffered oxide etch (BOE) for 20 seconds. No seams were observed, indicating that the film integrity is good. Similar results were observed after extended etch decoration in 20:1 BOE for 50 seconds.

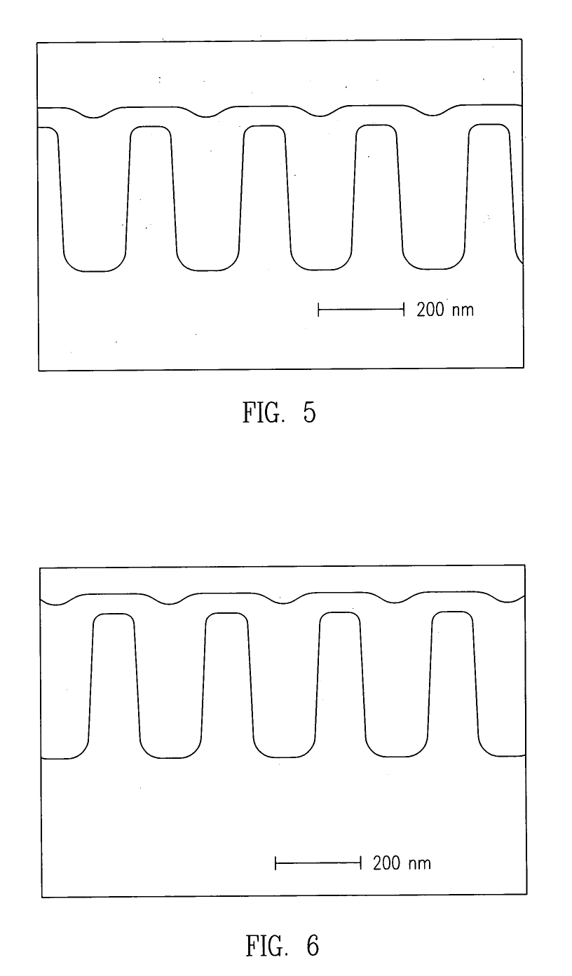

FIG. 6 is a graphical representation of an SEM photograph of a series of trenches that is identical to that of FIG. 5, but which were annealed after filled with undoped SiO₂ in accordance with the foregoing process. The anneal of the deposited film was performed at 1050° C. for 50 minutes in N₂. The as-annealed SiO₂ film shows complete gap fill after an extended etch decoration in 20:1 BOE for 80 seconds. No seams were observed, indicating that the film integrity is good.

The adequacy of step coverage was also explored. FIG. 7 is a graphical representation of an SEM photograph of an open step and wide gap trench which were conformally coated with undoped SiO₂ in accordance with the foregoing process. The as-deposited SiO₂ film after etch decoration in 20:1 BOE for 20 seconds shows good step coverage both over the open step and in the wide gap prior to filling with sufficient thickness.

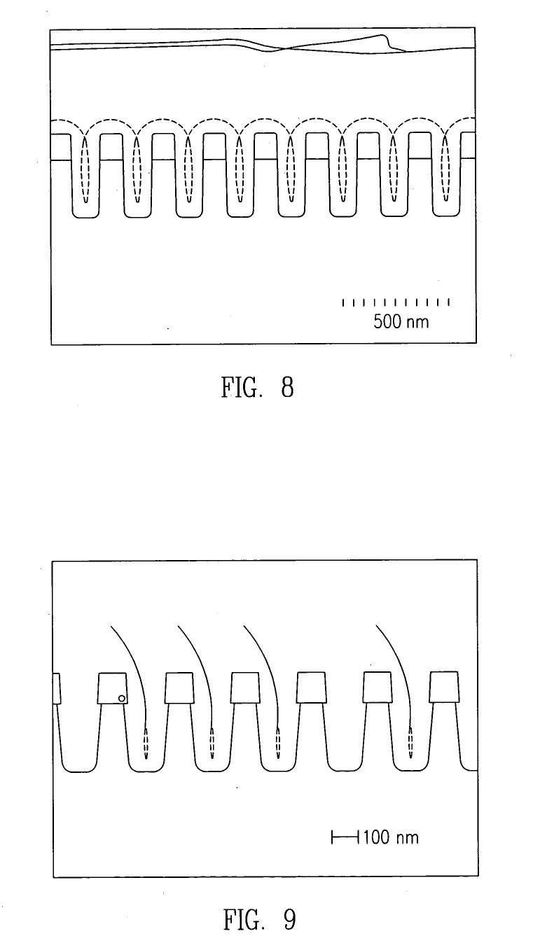

The problem of gap fill and seam weakness is better understood by consideration of views of semiconductor structures fabricated with prior art methods. FIG. 8 is a graphical representation of a SEM photograph of a series of trenches that is identical to that of FIG. 5, but which were filled with undoped SiO2 deposited by TEOS and O₃ without pretreatment, and which underwent etch decoration in 20:1 BOE for 20 seconds. The structure shows evidence of weak seams in the silicon dioxide film after only 20 seconds of etch decoration. The evidence is in the nature of gaps etched throughout the center of the silicon dioxide fill by the etch decoration. The gaps occur due to the lack of film integrity where the silicon dioxide growing from the trench sidewalls converge.

FIG. 9 is a graphical representation of a SEM photograph of a series of trenches that is identical to that of FIG. 8 filled with the same prior art process, except that the wafer was subsequently annealed at 1050° C. for 50 minutes in nitrogen, and received etch decoration in 20:1 BOE for 40 seconds. Weak seams are visible in four of the six trenches after only half the etch exposure than that withstood by films deposited by the foregoing method with pretreatment.

The foregoing method with pretreatment was used to fill both a narrow 0.13 micron gap and an extremely narrow 0.07 micron gap followed by deposition of a Si₃N₄ cap layer at 750° C. for less than about three minutes. The deposited silicon dioxide film exhibited minimal seam weakness after a 5 second 1:1:1 (equal parts water, 40 weight percent ammonium fluoride, and glacial acetic acid) etch decoration.

The foregoing method with pretreatment was also used to fill both a narrow 0.13 micron gap and an extremely narrow 0.07 micron gap with a relatively pronounced reentrant character, followed by anneal at 1000° C. for 30 minutes in N₂, followed by deposition of a Si₃N₄ cap layer. The as-annealed silicon dioxide in the 0.13 micron gap exhibited minimal seam weakness after a 5 minute LAL (similar to 200:1 BOE) etch decoration, although a void occurred in the 0.07 micron gap. The pronounced reentrant character of the small trench is believed to account for the void, which could be reduced by modification of the process parameters, i.e. by depositing thinner layers or by changing the duration of the pretreatment.

The description of the invention and its applications as set forth herein is illustrative, and is not intended to be exhaustive or to limit the scope of the invention. Variations and modifications of the embodiments disclosed herein are possible and will be apparent to those of ordinary skill in the art from a reading of this detailed description. These and other variations and modifications of the embodiments disclosed herein may be made without departing from the scope and spirit of the invention, as set forth in the following claims.

1. A method of forming a doped or undoped silicon-containing film upon a substrate having trenches therein, comprising:
pre-treating the substrate by chemical exposure in the absence of a silicon-containing source to improve uniformity within the trenches of a surface concentration of sites that are receptive to gas phase silicon-containing intermediates;
forming a layer of silicon-containing material upon the substrate by exposure of the substrate to a chemical vapor deposition gas source combination comprising an oxygen-containing source and a silicon-containing source; and
repeating the pre-treating step and the forming step to form a uniform film within the trenches.

2. The method of claim 1 further comprising determining a minimum width of the trenches, wherein each layer of silicon-containing material is formed with a thickness less than half the minimum width.

3. The method of claim 1 wherein the silicon-containing source in the layer forming step comprises one of silane, TEOS, OMCTS, TMCTS, HMDSO, TMDSO, or any combination thereof.

4. The method of claim 1 wherein the oxygen-containing source in the layer forming step comprises ozone.

5. The method of claim 1 wherein:
the chemical exposure in the pre-treating step is to an oxygen-containing source;
the silicon-containing source in the layer forming step comprises one of silane, TEOS, OMCTS, TMCTS, HMDSO, TMDSO, or any combination thereof;
the oxygen-containing source in the layer forming step comprises ozone; and
the oxygen-containing source in the pre-treating step is identical to the oxygen-containing source in the layer forming step.

6. The method of claim 1 wherein at least some of the trenches have a depth:width aspect ratio of about 2.0 or greater with a minimum width gap of about 140 nm or less.

7. The method of claim 1 wherein the layer of silicon-containing material formed in the forming step comprises undoped silicon dioxide having a thickness on the order of about 200 Å or less.

8. The method of claim 1 wherein:
the forming step comprises exposing the substrate in a first chamber; and
the pre-treating step comprises exposing the substrate in a second chamber different than the first chamber.

9. The method of claim 1 wherein:
the forming step comprises exposing the substrate to a first injector within a chamber; and
the pre-treating step comprises exposing the substrate to a second injector within the chamber, different than the first injector.

10. The method of claim 1 wherein:
the forming step comprises exposing the substrate to a flow of the chemical vapor deposition gas source combination for a first predetermined period of time from an injector within a chamber; and
the pre-treating step comprises exposing the substrate to a flow of the chemical for a second predetermined period of time from the injector.

11. The method of claim 1 wherein:
the forming step comprises exposing the substrate to a rapid pulse of the chemical vapor deposition gas source combination from an injector within a chamber; and
the pre-treating step comprises exposing the substrate to a rapid pulse of the chemical from the injector.

12. The method of claim 1 wherein the pre-treating step comprises exposing the substrate to a chemical specifically suited to the exposed substrate material to enhance uniform surface concentration within the trenches of sites that are receptive to gas phase silicon-containing intermediates.

13. The method of claim 12 wherein the chemical is one of ozone, oxygen, hydrogen, N2O, H2O, NF3, isopropyl alcohol, methyl alcohol, or a combination thereof.

14. A method of forming a doped or undoped silicon dioxide film upon a substrate, comprising:
successively depositing upon the substrate thin layers of doped or undoped silicon dioxide with chemical vapor deposition using an oxygen-containing source and a silicon-containing source to obtain a film of a desired thickness; and
between each of the successive thin layer depositions, exposing the substrate to the oxygen-containing source in the absence of the silicon-containing source.

15. The method of claim 14 further comprising:
exposing the substrate to the oxygen-containing source in the absence of the silicon-containing source prior to the successively depositing step.

16. The method of claim 14 further comprising:
between each of the successive thin layer deposition, exposing the substrate to a thermal treatment.

17. A method of forming a doped or undoped silicon dioxide film upon a substrate, comprising:
forming a first layer of doped or undoped silicon dioxide with chemical vapor deposition;
oxidizing the first layer; and
forming a second layer of doped or undoped silicon dioxide contiguous with the first layer with chemical vapor deposition.

18. The method of claim 17 further comprising:
oxidizing the second layer; and
forming a third layer of silicon dioxide contiguous with the second layer with chemical vapor deposition.

19. The method of claim 17 wherein the substrate comprises a plurality of structures defining a plurality of trenches, further comprising:
determining a minimum width of the trenches;
wherein the first layer of silicon dioxide is formed with a thickness less than half the minimum width; and
wherein the second layer of silicon dioxide is formed with a thickness less than half the minimum width.

20. The method of claim 19 wherein:
the minimum width is less than about 140 nm;
the thickness of the first layer is less than about 200 Å; and
the thickness of the second layer is less than about 200 Å.

21. The method of claim 17 wherein the silicon dioxide of the first and second layers is undoped.
